(19) United States
(12) Patent Application Publication
(10) Pub. No.: US 2010/0320592 A1
(43) Pub. Date: Dec. 23, 2010

(54) SEMICONDUCTOR DEVICE AND METHOD FOR MANUFACTURING THE SAME

(75) Inventors: Yasuhiro Takano, Gunma (JP); Hirokazu Fukuda, Gunma (JP); Atsushi Mashita, Gunma (JP)

Correspondence Address: MORRISON & FOERSTER LLP, 1650 TYSONS BOULEVARD, SUITE 400, MCLEAN, VA, 22102, US

(73) Assignees: SANYO Electric Co., Ltd., Moriguchi-shi (JP); SANYO Semiconductor Co., Ltd., Ora-gun (JP)

(21) Appl. No.: 12/521,700

(22) PCT Filed: Sep. 27, 2007
(86) PCT No.: PCT/JP2007/069427

§ 371 Date: Jun. 29, 2009

(30) Foreign Application Priority Data
Dec. 29, 2006 (JP) 2006-356732

(51) Int. Cl. H01L 23/49; H01L 21/60; H01L 21/56

(52) U.S. Cl. 257/692; 438/124; 257/E21.504; 257/E21.509; 257/784; 257/E23.024

(57) ABSTRACT

A semiconductor device in which overall thickness is reduced by suppressing the rising of a metal thin line and connection reliability is enhanced at the joint of metal thin line and other member during resin sealing. A method for manufacturing such semiconductor device is also provided. The semiconductor device (10A) comprises electrodes (12A, 12B, 12C), a semiconductor chip (13) bonded to the upper surface of the electrode (12A) formed in the shape of island, a metal thin line (15A) connecting the semiconductor chip (13) and the electrode (12C), a metal thin line (15B) connecting the semiconductor chip (13) and the electrode (12B), and a sealing resin (11) supporting those elements mechanically by sealing them integrally. The metal thin lines (15A, 15B) have planar shape curved convexly toward the upstream of the flow if the sealing resin (11) to be injected.

### REFERENCE TO RELATED APPLICATIONS

This application is a national stage application under 35 USC 371 of International Application No. PCT/JP2007/069427, filed Sep. 27, 2007, which claims priority from Japanese Patent Application Number JP 2006-356732, filed Dec. 29, 2006, the contents of which are incorporated herein by reference in their entirety.

### FIELD OF THE INVENTION

The present invention relates to a semiconductor device and a method of manufacturing the same, and more particularly to a semiconductor device having an improvement in the reliability of connection by a fine metal wire and a method of manufacturing the same.

### BACKGROUND OF THE INVENTION

Generally, a semiconductor device uses a fine metal wire for an electrical connection between a semiconductor chip and an electrode sealed within the semiconductor device. The fine metal wire has a long history of technological change, as distinct from a bump electrode or the like for use in flip chip or other applications, and thus is even now in use because of its reliability.

One example is shown for instance in FIGS. 14 and 15. FIG. 14 is a plan view of a semiconductor device 100 as seen from above, and FIG. 15 is a cross-sectional view thereof. As shown by a rectangular shape, reference numeral 103 denotes a semiconductor chip, which is here described as a transistor device. A bipolar transistor, a MOS transistor, or the like, for example, is employed as the semiconductor chip 103.

Three electrodes electrically connected to the above-mentioned semiconductor chip 103 are embedded within the semiconductor device 100. An island-shaped electrode 102A electrically, fixedly bonded to the underside of the above-mentioned semiconductor chip 103 is located on the left edge, and two electrodes 102B and 102C are located on the right edge. In other words, the electrode 102A forms a collector electrode, and the other electrodes 102B and 102C form an emitter electrode and a base electrode, respectively. Then, two bonding pads of the semiconductor chip 103 are connected respectively via fine metal wires 105A and 105B to the electrode 102C and the electrode 102B.

Then, the electrodes 102A, 102B and 102C, the semiconductor chip 103, and the fine metal wires 105A and 105B are integrally sealed with a sealing resin 101. In addition, the electrodes 102A, 102B and 102C are partially exposed to the outside from the sealing resin 101.

The fine metal wires 105A and 105B undergo ball bonding on the bonding pads of the semiconductor chip 103, and extend upward and then downward to inner leads (or the electrodes 102B and 102C) for stitch bonding, so that the height H of the peak of the fine metal wire 105A or the like above the top surface of the semiconductor chip 103 is relatively high, that is, from 100 to 150 μm (See FIG. 15).

Japanese Patent Application Publication No. Hei 9-298256 discloses, in FIGS. 1 and 2, a package in which the inner leads are disposed on both sides of the island; however, as is apparent also from FIG. 2, the shape of the fine metal wire is likewise parabolic, which in turn leads to limitation in the thickness of the package.

However, considering a manufacturing method for the above-mentioned semiconductor device, there is a problem of breaking of the fine metal wires 105A and 105B in formation of the sealing resin 101 for sealing the semiconductor chip 103 and so on.

The specific description is as follows. Four arrows shown in FIG. 14 indicate the direction of resin injection, and a rectangular region located directly under the arrows represents a gate 106. Resin sealing of the semiconductor chip 103 and so on involves loading the semiconductor chip 103, the electrode 102A, and so on in a cavity of a molding die, and injecting the sealing resin 101 in liquid form from the gate into the cavity, thereby effecting the sealing thereof with the sealing resin 101.

Resin pressures for injection from the gate 106 are of various magnitudes, and high resin injection pressure may lead to bending or breaking of the fine metal wire 105A or the like; however, under the present circumstances, a fine wire of relatively great thickness is used as the fine metal wire 105A or the like thereby to suppress the breaking or the like. Also, the thickness, shape or other configuration of the fine metal wire 105A is determined by the relative positions of the bonding pads of the semiconductor chip 103 and the inner lead (or the electrode 102B), or in accordance with a bonding device.

Referring to FIG. 14, the shape, in a plan view, of the fine metal wire 105A situated in the upper part of the drawing is curved convexly toward the gate 106, and the shape, in the plan view, of the fine metal wire 105B situated in the lower part of the drawing is curved convexly away from the gate 106. Thus, when the resin is injected from the gate 106, a point of connection of the fine metal wire 105A with the electrode 102A and the semiconductor chip 103 is subjected to the action of force pressing the point of connection. There is a small likelihood that the pressing force will cause the fine metal wire 105A to break at the point of connection. However, the shape, in the plan view, of the fine metal wire 105B is curved concavely toward the gate 106, and thus, the action of the resin pressure on the fine metal wire 105B leads to the action of tensile stress on a point of connection between the fine metal wire 105B and other members. The point of connection of the fine metal wire 105B is vulnerable to the tensile stress, and thus, there is a great likelihood that the resin pressure will cause the fine metal wire 105B to break at the point of connection.

In addition, there is a trend in portable terminals, for example small-sized equipment such as mobile telephones, toward lightness, thinness, shortness and smallness, and various semiconductor packages as mounted on these are eagerly desired to likewise become thinner. Then, an attempt to suppress a rise in the fine metal wire 105A in order to achieve a reduction in the thickness of the package can possibly lead to the likelihood that deterioration will occur in mechanical strength at the point of connection between the fine metal wire 105A and other members, and thus, the above-mentioned breaking of the wire, involved in the resin injection, will manifest itself. The reason is that, if the fine metal wire 105A is formed into a low loop, the fine metal wire 105A is plastically deformed in complicated form in the vicinity of the point of connection between the fine metal wire 105A and other members.

### SUMMARY OF THE INVENTION

The present invention has been made in order to solve the foregoing problems. A principal object of the present invention is to provide a semiconductor device and a method of manufacturing the same, which achieve a reduction in the overall thickness by suppressing the rise in the fine metal wire, and also achieve an increase in the reliability of connection at the point of connection between the fine metal wire and other members at the time of the resin sealing.

A semiconductor device of the present invention comprises: a semiconductor chip; an electrode provided around the semiconductor chip; a fine metal wire that connects a bonding pad on the semiconductor chip and the electrode; and a sealing resin that seals the semiconductor chip, the electrode and the fine metal wire. Here, the sealing resin is injected into a cavity formed by a molding die from one side of the cavity, and the fine metal wire is curved convexly toward an inlet for the injection, as viewed in a plan view.

Further, a semiconductor device of the present invention comprises: a semiconductor chip; an electrode provided around the semiconductor chip; a fine metal wire that connects a bonding pad on the semiconductor chip and the electrode; and a sealing resin that seals the semiconductor chip, the electrode and the fine metal wire. Here, the fine metal wire is curved as viewed in a plan view, in such a manner that fixedly bonded portions located on both ends of the fine metal wire are pressurized by injection pressure of the sealing resin.

Furthermore, a semiconductor device of the present invention comprises: a rectangular semiconductor chip; a plurality of bonding pads provided along four side edges of the semiconductor chip; a plurality of electrodes surrounding the semiconductor chip and provided in close proximity to locations corresponding to the bonding pads, respectively; and a sealing resin that seals the semiconductor chip, the electrodes and the fine metal wires. Here, the sealing resin is injected along an extension line of a diagonal line of the semiconductor chip, and each of the fine metal wires is curved convexly against a flow of the sealing resin from an inlet for injection, as viewed in a plan view.

A method of manufacturing a semiconductor device of the present invention, comprises the steps of: connecting a bonding pad provided on a top surface of a semiconductor chip, to an electrode provided in close proximity to the semiconductor chip, by a fine metal wire; and loading the semiconductor chip, the fine metal wire and the electrode in a cavity of a molding die, and injecting a sealing resin from a gate provided in a side edge of the cavity into the cavity, and thereby sealing the semiconductor chip, the fine metal wire and the electrode with the sealing resin. Here, wherein a shape, in a plan view, of the fine metal wire is curved convexly upstream of a flow of the sealing resin injected from the gate.

FIG. 3 is a plan view of a fine metal wire 15A as seen from above the top surface of a package. As can be seen also from vectors shown in this drawing, the fine metal wire 15A is curved opposite to (i.e., upstream of) the direction (indicated by F1 to F3) of flow of the resin injected from the gate, and thereby, forces exerted on both ends of the fine metal wire 15A act as compression rather than tension. Moreover, as shown by a vector diagram, the forces are lessened to form forces F2a and F3a and thereby improve the reliability.

As otherwise expressed, the fine metal wire is formed in such a manner as to extend in a direction (i.e., the direction from top to bottom of the drawing) crossing (or perpendicular to) the direction of the flow of the resin (flowing horizontally in the direction from left to right), and to curve convexly against the resin flow (indicated by F1 to F3) (i.e., to curve convexly in the direction from right to left). Thereby, forces exerted on both ends of the fine metal wire act as compression or pressurization, rather than tension, and moreover, as shown by the vector diagram, forces of smaller magnitude than that of originally applied injection pressure (indicated by F1 to F3) act to thus prevent separation of the fine metal wire.

### BRIEF DESCRIPTION OF THE DRAWINGS

FIG. 1 is a plan view showing a semiconductor device of the present invention.

FIG. 2 is a cross-sectional view showing the semiconductor device of the present invention.

FIG. 3 is a view showing the semiconductor device of the present invention, with a fine metal wire 15A subjected to the action of force involved in resin sealing.

FIGS. 4A and 4B are views showing a comparison, illustrating the fine metal wire of the present invention as subjected to the action of force F1, and a fine metal wire of a comparative example as subjected to the action of force F1, respectively.

FIGS. 5A, 5B and 5C are a plan view, a cross-sectional view and a cross-sectional view, respectively, showing semiconductor devices of the present invention.

FIG. 6 is a plan view showing a semiconductor device of the present invention.

FIG. 7 is a plan view showing a semiconductor device of the present invention.

FIG. 8 is a cross-sectional view showing a semiconductor device of the present invention.

FIG. 9 is a plan view showing the semiconductor device of the present invention.

FIG. 10 is a plan view showing a method of manufacturing a semiconductor device of the present invention.

FIGS. 11A to 11F are cross-sectional views showing the method of manufacturing the semiconductor device of the present invention.

FIGS. 12A to 12E are cross-sectional views showing the method of manufacturing the semiconductor device of the present invention.

FIGS. 13A and 13B are cross-sectional views showing the method of manufacturing the semiconductor device of the present invention.

FIG. 14 is a plan view showing a background-art semiconductor device.

FIG. 15 is a cross-sectional view showing the background-art semiconductor device.

### DETAILED DESCRIPTION OF THE INVENTION

Description will be given below of a semiconductor device according to the present invention. In FIG. 1 and other drawings, description will be given of a package (or a semiconductor device) having a discrete type transistor embedded therein by way of example; however, it goes without saying that the present invention may be otherwise applied. In short, any one of an IC, an LSI, and a system LSI, or a combination of two or more of these may be embedded in the semiconductor device of the present invention. Further, a BIP type transistor, a power MOS, an IGBT, a GTBT, a BIP type IC or LSI, a MOS type IC or LSI, or furthermore, a BiCMOS type LSI, or the like may be used as a semiconductor chip to be embedded in the semiconductor device.

### First Embodiment

In the first embodiment, description will be given, with reference to FIGS. 1 to 9, of a configuration of a semiconductor device 10A and so on, and a sealing method therefor.

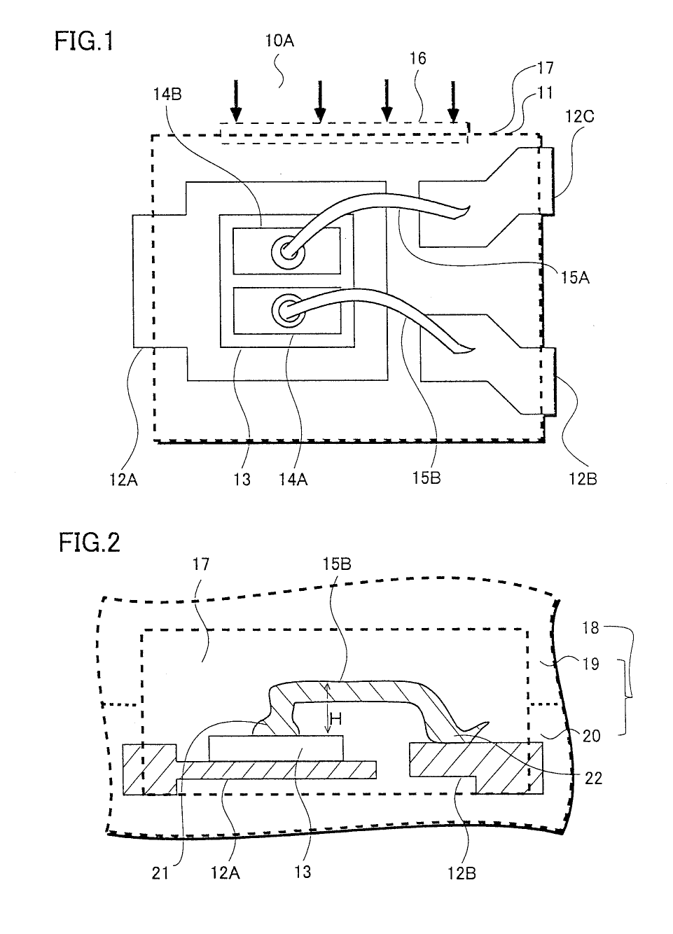

Firstly, description will be given, with reference to FIGS. 1 and 2, of the configuration of the semiconductor device 10A according to the first embodiment, and so on. Incidentally, FIG. 1 is a plan view of the semiconductor device 10A that forms a rectangular semiconductor package, and FIG. 2 is a cross-sectional view of the semiconductor device 10A taken along a fine metal wire 15B. Further, with reference to these drawings, a manufacturing method will also be described. Accordingly, these drawings also show a cavity 17 and a gate 16 of a molding die for use in resin sealing.

The semiconductor device 10A is configured by generally including electrodes 12A, 12B and 12C, a semiconductor chip 13 fixedly bonded to the top surface of the electrode 12A formed in the shape of an island, a fine metal wire 15A that connects the semiconductor chip 13 and the electrode 12C, the fine metal wire 15B that connects the semiconductor chip 13 and the electrode 12B, and a sealing resin 11 that integrally seals these components and thereby mechanically supports them.

In other words, the semiconductor device 10A is constructed to form what is called a lead frame type package. Specifically, the semiconductor chip 13 is fixedly bonded to the top surface of the island formed of a portion of the electrode 12A. Then, the electrodes 12B and 12C are each formed of an outer lead that forms an exposed portion exposed to the outside from the sealing resin 11, and an inner lead that forms a coated portion coated with the sealing resin 11. Further, the fine metal wires 15B and 15A are wire-bonded to the top surfaces of the inner lead portions of the electrodes 12B and 12C, respectively.

The semiconductor chip 13 is fixedly bonded to the top surface of an island-shaped region of the electrode 12A with a solder material or conductive paste such as silver paste in between. Then, the top surface of the semiconductor chip 13 is provided with two bonding pads 14A and 14B. Further, an electrode, not shown, is formed also on the underside of the semiconductor chip 13. A MOS transistor is here used by way of example as the semiconductor chip 13, and there, the bonding pads 14A and 14B serve as a gate electrode and a source electrode, respectively, and the electrode on the underside of the semiconductor chip 13 serves as a drain electrode.

The electrodes 12A, 12B and 12C are connected to the semiconductor chip 13 and are partially exposed to the outside from the sealing resin 11. The electrode 12A is such that the left end thereof, as seen in the drawing, is exposed to the outside, that the right region thereof is formed wider than other regions into the shape of the island, and that the underside of the semiconductor chip 13 is fixedly bonded and electrically connected to the top surface of the island-shaped region. The electrode 12B is such that the fine metal wire 15B is connected to the top surface of a left region of the electrode 12B, and that the right end of the electrode 12B is exposed to the outside from the sealing resin 11. As is the case with the electrode 12B, the electrode 12C is likewise such that the fine metal wire 15A is connected to the top surface of a left region of the electrode 12C, and that the right end of the electrode 12C is exposed to the outside from the sealing resin 11.

Referring to the cross-sectional view of FIG. 2, the right island-shaped region of the electrode 12A is formed thinner than a left region thereof. Specifically, the electrode 12A is such that the top surface of the right island-shaped region is located below the left area exposed to the outside. Meanwhile, the underside of the right island-shaped region is located above the left area exposed to the outside. The top surface of the island-shaped region of the electrode 12A is located at low level thereby to enable the lowering of the position of the semiconductor chip 13 and the fine metal wire 15B fixedly bonded to this region, thus permitting a reduction in the thickness of the semiconductor device 10A. Incidentally, the sealing resin 11 also extends beneath the island-shaped portion of the electrode 12A.

Further, the electrodes 12B and 12C, likewise, are each such that the underside of the left region (i.e., the region whose top surface has a connection to the fine metal wire 15A or the like) is located above the underside of the right area exposed to the outside. Then, the electrodes 12B and 12C, likewise, are each such that the sealing resin 11 extends beneath the left region.

The fine metal wires 15A and 15B have the function of providing electrical connections between the bonding pads 14A and 14B provided on the top surface of the semiconductor chip 13 and the electrodes 12B and 12C. For example, the fine metal wires 15A and 15B are the fine wires made of gold, each having a diameter of about 20 μm. A specific configuration of the fine metal wire, as described with reference to FIG. 2, is such that the fine metal wire 15B is ball bonded to the bonding pad of the semiconductor chip 13, extends upward about 50 μm, is then bent in an L shape, or equivalently, into substantially a 90° angle, extends obliquely downwardly from outside an edge of the semiconductor chip 13 in the neighborhood of one end of the electrode 12B in order to avoid the edge, and is stitch bonded to the top surface of the electrode 12B. The height H of a horizontally extending portion of the fine metal wire 15B above the top surface of the semiconductor chip 13 is about 50 μm. This configuration is the same, as for the fine metal wire 15A.

Here, a method other than ball bonding may be used as a method for forming the fine metal wire 15B, and for example, wedge bonding may be used to form the fine metal wire 15B.

The sealing resin 11 is injection-molded by using the molding die, and specifically, transfer molding using a thermosetting resin or injection molding using a thermoplastic resin is used to form the sealing resin 11. The side of the sealing resin 11 is formed slightly obliquely, allowing for removal from the molding die. However, generally, the outer shape of the package made of the sealing resin 11 is a cube or a rectangular parallelepiped. In other words, a top, a bottom, and four sides that link the top and the bottom form the outer shape formed of the sealing resin 11.

A feature of the present invention is that the shapes, in a plan view, of the fine metal wires 15A and 15B are curved convexly upstream of the flow of the injected sealing resin 11.

Specifically, referring to FIG. 2, a method for forming the sealing resin 11 is as follows. First, the electrode 12A and so on, the semiconductor chip 13, and the fine metal wire 15B and so on are loaded in the cavity 17 of a die 18 formed of a top die 19 and a bottom die 20. Then, the sealing resin 11 in liquid form is injected from the gate 16 (see FIG. 1) provided in the die 18 into the cavity 17. Finally, the sealing resin 11 is thermally cured as needed, and then, the sealing resin 11 is unloaded from the die 18. Therefore, the sealing resin 11 in liquid form is injected from the gate 16, and thus, at the time of the resin sealing, a downward pressure from above the sheet as seen in the drawing acts on the fine metal wires 15A and 15B. Then, a deformation, a break or the like can possibly occur in the fine metal wires 15A and 15B unless measures against this stress are taken.

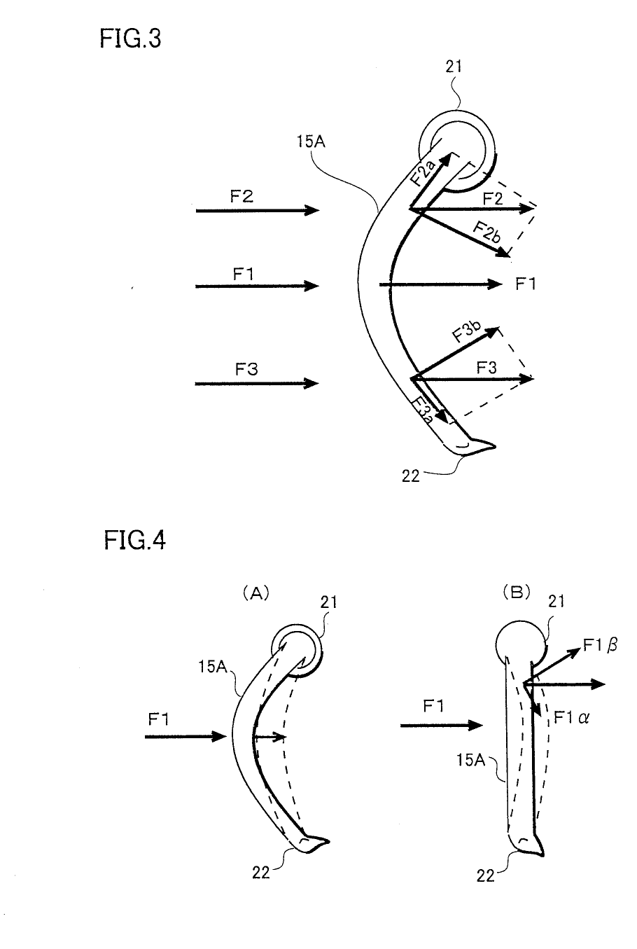

In this embodiment, the shapes, in the plan view, of the fine metal wires 15A and 15B are devised thereby to prevent their deformation or breaking. Specifically, referring to FIG. 1, the two fine metal wires 15A and 15B are used in the semiconductor device 10A, and the shapes, in the plan view, of both the fine metal wires 15A and 15B are looped so as to curve convexly in upward directions. In other words, the fine metal wires 15A and 15B are looped convexly upstream of (i.e., opposite to) the flow of the sealing resin 11 in liquid form injected from the gate 16. The fine metal wires 15A and 15B have this configuration, and thereby, even if pressure produced by the sealing resin 11 injected from the gate 16 acts, forces acting on points of connection between the fine metal wires 15A and 15B and other members are pressing forces (or compressive forces), and thus, the breaking at the points of connection is suppressed. Further, the above-mentioned curved configuration also lessens the force acting on the point of connection thereby to prevent the fine metal wire 15A from becoming broken or deformed. Details of this will be described later with reference to FIG. 3.

Here, in other words, the curved configuration of the fine metal wire 15A or the like, which is a point of the present invention, is such that the fine metal wire 15A is curved convexly toward the gate 16 from which the sealing resin 11 is injected. Further, the shape, in the plan view, of the fine metal wire 15A or the like is such a curved shape that pressurizing force acts on fixedly bonded portions 21 and 22 (see FIG. 3) (that is, tensile force does not acts thereon), even if the pressure of the injected sealing resin 11 acts.

A further feature of the present invention is that the above-mentioned shape in the plan view is applied to a fine metal wire with a low loop. Specifically, referring to FIG. 2, the configuration of the fine metal wire 15B is not an arched configuration, but a configuration such that most part of the fine metal wire 15B extends parallel to the top surface of the semiconductor chip 13. Specifically, referring to this drawing, the fine metal wire 15B has the fixedly bonded portion 21 at the left end, and has the fixedly bonded portion 22 at the right end. Then, a portion (i.e., an intermediate portion) of the fine metal wire 15B, exclusive of the vicinities of both the fixedly bonded portions, extends parallel to the top surface of the electrodes 12A and 12B. This configuration is implemented thereby to lower the position of the topmost portion of the fine metal wire 15B and thus reduce the thickness of the overall semiconductor device 10A.

However, the implementation of this configuration leads to deterioration of mechanical strength at the point of connection (i.e., the fixedly bonded portion 21) between the bonding pad of the semiconductor chip 13 and the fine metal wire 15B. Therefore, if the pressure from the sealing resin 11 acts on the fine metal wire 15B with the low loop, a break can possibly occur at the point of connection (i.e., the fixedly bonded portion 21) between the fine metal wire 15B and the semiconductor chip 13. Therefore, in the first embodiment, as mentioned above, the shape, in the plan view, of the fine metal wire 15B is such that the fine metal wire 15B is curved convexly upstream of the flow of the sealing resin 11 injected. Thereby, tensile stress does not act on the point of connection between the semiconductor chip 13 and the fine metal wire 15B. Thus, this point of connection is subjected to the action of pressing stress and tends to be resistant to the pressing stress rather than the tensile stress, and thus, a break at the point of connection is prevented. Details of a method for forming the fine metal wire 15B with the low loop will be described later.

Further, in this embodiment, in order to improve heat radiation properties, the sealing resin 11 may be made of a resin material containing mixed therein an inorganic filler such as silica. In this instance, the sealing resin 11 in liquid form has a high viscosity, and thus, in a process for the resin sealing, the force of the injected sealing resin 11 acting on the fine metal wire 15A or the like becomes large. However, in the first embodiment, as mentioned above, the fine metal wire 15A or the like is curved upstream of the flow of the sealing resin 11 injected, and thus, the breaking of the fine metal wire 15A or the like is suppressed.

Stress acting on the fine metal wire 15A will be specifically described with reference to FIGS. 3 and 4. In FIGS. 3 and 4, the fine metal wire 15A extends in the direction from top to bottom, the upper end is the fixedly bonded portion 21 connected to the semiconductor chip (not shown), and the lower end is the fixedly bonded portion 22 connected to the top surface of the electrode.

Referring to FIG. 3, the magnitude and direction of pressure produced by the sealing resin is indicated by the arrows designated by F1 to F3. Here, pressure acting on the vicinity of a central portion of the fine metal wire 15A is indicated by F1, pressure acting on the vicinity of the fixedly bonded portion 21 on the upper end is indicated by F2, and pressure acting on the vicinity of the fixedly bonded portion 22 on the lower end is indicated by F3. Then, F1 to F3 act in the direction from left to right in the drawing. This direction is the same as the flowing direction of the sealing resin in liquid form. Further, the magnitudes of F1 to F3 are substantially the same.

The shape, in the plan view, of the fine metal wire 15A is such that the fine metal wire 15A is curved, while projecting out in a direction opposite to the direction of action of F1 to F3 (that is, leftward as seen in the drawing). With this configuration, forces acting on the fixedly bonded portions 21 and 22 are compressive forces, and also, the forces acting on the fixedly bonded portions 21 and 22 in themselves can be lessened thereby to prevent the separation of the fine metal wire 15A from the fixedly bonded portions 21 and 22.

Specifically, first, F1 acts on the central portion of the fine metal wire 15A and causes slight elastic deformation in the fine metal wire 15A. However, most of F1 is accommodated by the fine metal wire 15A becoming slightly deformed, and thus, the fine metal wire 15A does not undergo great plastic deformation, so that F1 does not have an adverse influence on the fine metal wire 15A.

F2 acting on the fine metal wire 15A in the vicinity of the fixedly bonded portion 21 is resolved into a force F2a parallel to a tangent to the curved fine metal wire 15A, and a force F2b perpendicular to the tangential direction. The force acting on the fixedly bonded portion 21 is the resolved force F2a, and the magnitude of F2a is small as compared to the original force F2, and thus, the separation of the fine metal wire 15A from the fixedly bonded portion 21 is prevented. For example, if the direction of action of F2 and the tangent to the fine metal wire 15A intersect at an angle of 45 degrees, the magnitude of F2a is about 0.7 time that of F2.

Further, as mentioned above, if the fine metal wire 15A has the low loop, the shape of the fine metal wire 15A in the vicinity of the fixedly bonded portion 21 becomes complicated and thus the breaking of the wire can possibly occur; however, the fine metal wire 15A is curved in a specific direction thereby prevent the breaking of the wire.

On the other hand, F3 acting on the vicinity of the fixedly bonded portion 22 on the lower end can also be resolved in the same manner as described above. Specifically, F3 is resolved into a force F3a parallel to a tangent to the fine metal wire 15A in the vicinity of the fixedly bonded portion 22, and a force F3b perpendicular to the tangent. Then, compressive force acting on the fixedly bonded portion 22 of the fine metal wire 15A is F3a that is smaller than F3, and thus, the breaking of the wire in the fixedly bonded portion 22 is prevented.

A further feature of this embodiment will be described with reference to FIG. 4. FIG. 4A shows the shape of the fine metal wire 15A of the first embodiment, and FIG. 4B shows the fine metal wire 15A as formed in a straight line.

Referring to FIG. 4A, the pressure F1 involved in the resin sealing acts on the fine metal wire 15A from the left side in the drawing. The action of the force F1 leads to deformation in the fine metal wire 15A as shown by dotted lines, and hence to the action of compressive forces on the fixedly bonded portions 21 and 22. However, as mentioned above, the fine metal wire 15A is curved convexly leftward, and thus, forces resolved along the tangential direction of the fine metal wire 15A act on the fixedly bonded portions 21 and 22. Thus, the breaking of the fine metal wire 15A in the vicinity of the fixedly bonded portions 21 and 22 is suppressed. Further, the action of the force F1 causes the deformation in the fine metal wire 15A as shown by the dotted lines; however, this deformation is elastic deformation, and thus, when the force F1 is released, the fine metal wire 15A is restored to its original shape.

A comparative example will be described with reference to FIG. 4B. Here, discussion is made of an instance where the shape, in the plan view, of the fine metal wire 15A is in the form of a straight line rather than a curved line. When the force F1 acts on the fine metal wire 15A formed in a straight line, the fine metal wire 15A is deformed into a curved form projecting rightward (as shown by dotted lines). When the fine metal wire 15A is deformed in this manner, the force F1 exerted on the fixedly bonded portion 21 is resolved into a force F1α parallel to the tangent to the deformed fine metal wire 15A, and a force F1β perpendicular to the tangent. Then, the force F1α is tensile force, and the action of the tensile force F1α on the fine metal wire 15A leads to the likelihood that the breaking of the fine metal wire 15A will occur in the vicinity of the fixedly bonded portion 21. The same goes for the fine metal wire 15A in the vicinity of the fixedly bonded portion 22.

From the above discussion, it has been shown that, for the shape, in the plan view, of the fine metal wire 15A, a form such that the fine metal wire 15A is curved convexly upstream of the flow of the sealing resin 11 is preferable to the straight-line form, allowing for the pressure of the sealing resin 11 being injected.

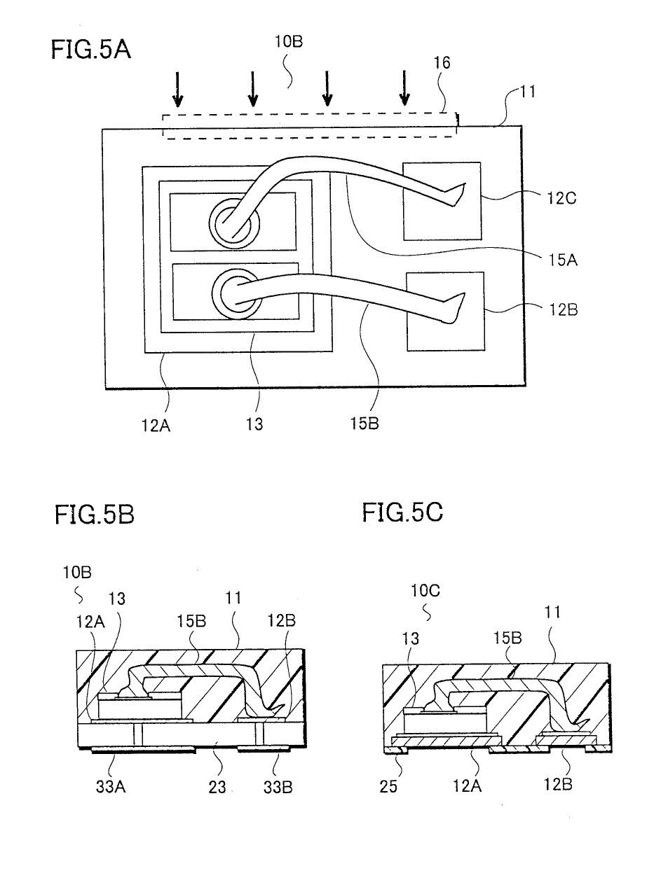

Description will be given, with reference to FIGS. 5A to 5C, of a configuration of a semiconductor device 10B of another form. FIG. 5A is a plan view of the semiconductor device 10B as seen from above, FIG. 5B is a cross-sectional view thereof, and FIG. 5C is a cross-sectional view of a semiconductor device 10C of another form.

A basic configuration of the semiconductor device 10B shown in FIGS. 5A and 5B is the same as that of the above-mentioned semiconductor device 10A, and a difference lies in the configuration of the electrode 12A or the like. In the semiconductor device 10B shown here, the electrodes 12A, 12B and 12C are disposed on the top surface of a circuit board 23 made of an insulating material such as glass epoxy, and the semiconductor chip 13 is disposed on the top surface of the electrode 12A. Then, two bonding pads formed on the top surface of the semiconductor chip 13 are connected respectively via the fine metal wires 15A and 15B to the electrodes 12C and 12B.

Also in the semiconductor device 10B, the shapes, in the plan view, of the fine metal wires 15A and 15B are curved convexly upstream of the flow of the sealing resin 11 being injected from the gate 16.

Referring to FIG. 5B, here, the electrodes 12A, 12B and 12C (not shown) are formed on the top surface of the circuit board 23. Then, the circuit board 23 is provided with a conductive material (or through connections) such as copper, formed through the circuit board 23 in the direction of thickness thereof. The electrodes 12A, 12B and 12C provided on the top surface of the circuit board 23 are connected respectively via the through connections to underside electrodes 33A, 33B and 33C (not shown) provided and exposed on the underside of the circuit board 23. An external connection electrode made of a conductive adhesive material such as solder is welded to the underside electrode 33A or the like, and the external connection electrode is used for surface mounting of the semiconductor device 10B on the top surface of a packaging board or the like.

Here, besides the above-mentioned single-layer glass epoxy substrate, various materials may be used as the circuit board 23 of the semiconductor device 10B. For example, a printed board made of a resin substrate whose surface is provided with a wiring layer of a predetermined configuration, a flexible sheet made of a flexible resin sheet provided with a predetermined wiring layer, a metal substrate made of metal whose top surface is coated with an insulating layer made of an insulating material such as a resin, a substrate made of an inorganic material such as ceramics, or the like may be used as the circuit board 23. Here, if a wiring layer is provided on the top surface of the circuit board 23, a multilayer wiring structure having two or more wiring layers stacked one on top of another with an interlayer dielectric in between may be used.

Description will be given, with reference to FIG. 5C, of a configuration of the semiconductor device 10C of another form. A basic configuration of the semiconductor device 10C is the same as that of the above-mentioned semiconductor device 10B, and a difference lies in that the electrode 12A or the like is partially exposed to the outside from the sealing resin 11. Description will be given below, centering on this point of difference.

The semiconductor device 10C is configured by including the electrodes 12A, 12B and 12C (not shown), the semiconductor chip 13 fixedly bonded to the top surface of the electrode 12A, the fine metal wire 15B that provides an electrical connection between the semiconductor chip 13 and the electrode 12B, and the sealing resin 11 that seals these components. Then, the electrode 12A or the like is coated at the top and side with the sealing resin 11 and is exposed, at the underside, to the outside from the sealing resin 11. In addition, the underside of the electrode 12A or the like and the underside of the sealing resin 11, exclusive of an area where the external connection electrode such as solder is welded to the electrode 12A or the like, are coated with a resist 25 made of a resin.

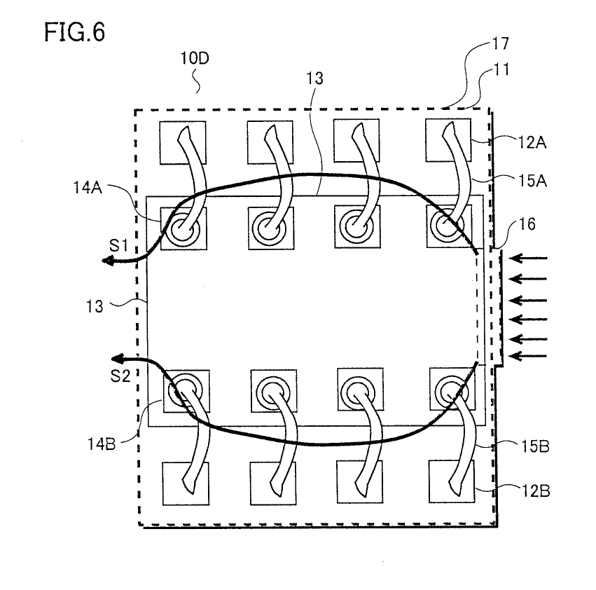

Description will be given, with reference to FIG. 6, of a configuration of a semiconductor device 10D of another form. A basic configuration of the semiconductor device 10D is the same as that of the above-mentioned semiconductor device 10B or the like, and differences lie in bonding pads provided on the top surface of the semiconductor chip 13, and the configuration of electrodes 12.

The points of difference, as described specifically, are as follows. Firstly, the top surface of the semiconductor chip 13 is provided with many bonding pads. Here, multiple bonding pads 14A are disposed along an upper side edge of the semiconductor chip 13 as seen in the drawing, and multiple bonding pads 14B are disposed along a lower side edge thereof. Then, many electrodes 12 are provided in close proximity to the semiconductor chip 13. Specifically, as seen in the drawing, multiple electrodes 12A are provided above the semiconductor chip 13, and multiple electrodes 12B are provided under the semiconductor chip 13. In addition, the bonding pads 14A provided along the upper side edge of the semiconductor chip 13 are connected respectively via the fine metal wires 15A to the electrodes 12A. Likewise, the bonding pads 14B provided along the lower side edge of the semiconductor chip 13 are connected respectively via the fine metal wires 15B to the electrodes 12B.

Here, the shapes, in the plan view, of the fine metal wires 15A and 15B are curved convexly upstream of the flow of the sealing resin being injected from the gate 16 into the cavity 17. Referring to the drawing, the shapes, in plan view, of all fine metal wires 15A and 15B are curved convexly rightward and curved convexly upstream of flows S1 and S2 of the sealing resin being injected from the gate 16. As mentioned above, this enables the prevention of the deformation and breaking of the fine metal wire 15A by the pressure of the sealing resin 11 being injected.

Specifically, when, in a molding process, the sealing resin 11 in liquid form is injected from the gate 16 into the cavity 17, the injected sealing resin 11 flows preferentially between the semiconductor chip 13 and the electrodes 12A and 12B. Here, the flow of the sealing resin 11 flowing preferentially between the semiconductor chip 13 and the electrodes 12A is shown by a solid line indicated by 51, and the flow of the sealing resin 11 flowing preferentially between the semiconductor chip 13 and the electrodes 12B is shown by a solid line indicated by S2. Here, the fine metal wires 15A and 15B alone are present in the direction of thickness in regions between the semiconductor chip 13 and the electrodes 12A and 12B, and thus, these regions are environment in which the sealing resin 11 is flowable as compared to other areas.

When the sealing resin 11 is injected along S1 and S2, pressure by the sealing resin 11 acts on the fine metal wires 15A and 15B; however, also in this case, the shapes, in the plan view, of the fine metal wires 15A and 15B are curved convexly against the flow of the sealing resin 11, thereby preventing damage to the fine metal wires 15A and 15B by this pressure. This mechanism is as mentioned above.

Here, a configuration such as is shown in FIG. 5B or a configuration such as is shown in FIG. 5C may be used as a cross-sectional configuration of the semiconductor device 10D. Further, a configuration such that the underside of the semiconductor chip is exposed to the outside from the sealing resin 11 may be used.

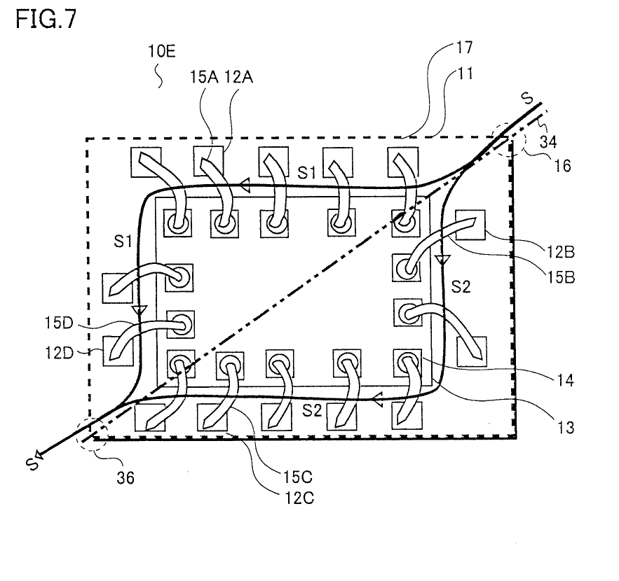

Description will be given, with reference to FIG. 7, of a configuration of a semiconductor device 10E of another form. A basic configuration of the semiconductor device 10E is the same as that of the above-mentioned semiconductor device 10D, and a difference lies in that the electrodes 12A and the like are provided so as to surround the semiconductor chip 13 from four directions.

Specifically, the top surface of the semiconductor chip 13 is provided with many bonding pads 14 along four side edges thereof, and electrodes are disposed in locations corresponding to the bonding pads, respectively. Specifically, multiple electrodes 12A, 12B, 12C and 12D are disposed along the upper side edge, right side edge, lower side edge and left side edge, respectively, of the semiconductor chip 13, as seen in the drawing. Then, the electrodes 12A, 12B, 12C and 12D disposed so as to surround the semiconductor chip 13 from four directions are connected respectively via the fine metal wires 15A, 15B, 15C and 15D to the bonding pads 14 on the top surface of the semiconductor chip 13.

Also in the semiconductor device 10E, the shape, in the plan view, of the fine metal wires 15A and the like are curved convexly upstream of the flow of the sealing resin 11 being injected from the gate. Specifically, first, the gate 16 provided in the cavity 17 of the molding die lies on an extension line 34 of a diagonal line that links corners of the semiconductor chip 13 placed in the cavity 17. Here, the extension line 34 is shown by a dash-double dot line, and the gate 16 is provided in a location such that the gate 16 overlaps the extension line 34. Further, here, an air vent 36 is likewise provided in a location such that the air vent 36 overlaps the extension line 34.

When the sealing resin 11 in liquid form (or in semisolid form) is injected from the gate 16 into the cavity 17 of the above-mentioned configuration, the injected sealing resin 11 first moves toward the corner of the semiconductor chip 13. In the drawing, this flow is indicated by S. Then, the sealing resin 11 is divided into two branches in the vicinity of the corner of the semiconductor chip 13. One of the branches is the flow of the sealing resin 11 along a space between the upper side edge of the semiconductor chip 13 and the electrodes 12A, as seen in the drawing (i.e., the flow 51). The other branch is the flow of the sealing resin 11 along a space between the right side edge of the semiconductor chip 13 and the electrodes 12B, as seen in the drawing (i.e., the flow S2). The reason why the sealing resin 11 flows preferentially between the semiconductor chip 13 and the electrodes 12A and the like is as mentioned above.

The flow S1 is the flow of the sealing resin 11 starting at the upper right end of the semiconductor chip 13 and flowing along the upper side edge to the lower left end thereof. Specifically, the flow S1 is such that the sealing resin 11 passes between the upper side edge of the semiconductor chip 13 and the electrodes 12A and then passes between the left side edge of the semiconductor chip 13 and the electrodes 12D.

On the other hand, the flow S2 is the same as the flow S1 in the starting point and endpoint but is different in route. Specifically, the flow S2 is such that the sealing resin 11 flows between the right side edge of the semiconductor chip 13 and the electrodes 12B and then flows along a space between the lower side edge of the semiconductor chip 13 and the electrodes 12C.

Then, the flows S1 and S2 are combined into the flow S in the vicinity of the lower left end of the semiconductor chip 13. In addition, as the sealing resin 11 is injected from the gate 16 into the cavity 17, air in the cavity 17 is released to the outside through the air vent 36 by an equivalent amount to the injected sealing resin 11.

Then, the shapes, in the plan view, of the fine metal wires 15A and the like are curved convexly upstream of the above-mentioned flow of the sealing resin 11. Specifically, the fine metal wires 15A provided on the upper side edge of the semiconductor chip 13 are curved convexly rightward as seen in the drawing. Then, the fine metal wires 15B provided on the right side edge of the semiconductor chip 13 are curved convexly upward. In addition, the fine metal wires 15C provided on the lower side edge of the semiconductor chip 13 are curved convexly rightward. Further, the fine metal wires 15D provided on the left side edge of the semiconductor chip 13 are curved convexly upward.

With the above-mentioned configuration, the shapes, in the plan view, of all fine metal wires 15A and the like having connections to the bonding pads 14 can be curved convexly upstream of the flows of the sealing resin 11, even if the top surface of the semiconductor chip 13 is provided with the bonding pads 14 along the four side edges thereof. This enables the prevention of the breaking of the fine metal wires 15A and the like by the pressure of the sealing resin 11 being injected.

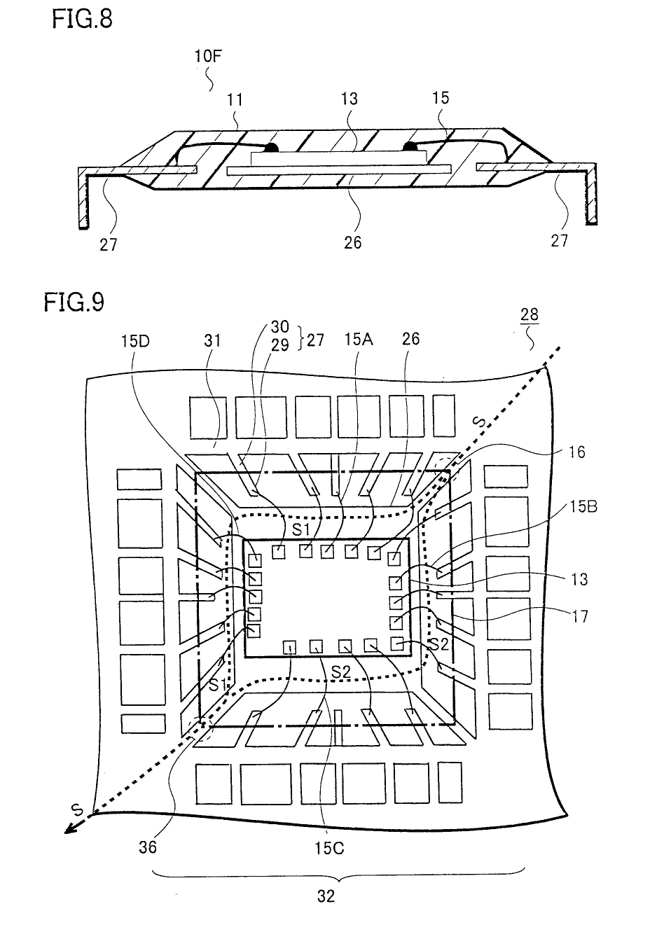

Description will now be given, with reference to FIGS. 8 and 9, of a configuration of a semiconductor device 10F of another form. FIG. 8 is a cross-sectional view of the semiconductor device 10F, and FIG. 9 is a plan view of the semiconductor device 10F as being sealed with the resin.

Referring to FIG. 8, a basic configuration of the semiconductor device 10F is the same as that of the above-mentioned semiconductor device 10E, and a difference lies in that the semiconductor device 10F is of a lead frame type.

The semiconductor device 10F includes an island 26 and a lead 27, and the semiconductor chip 13 is fixedly bonded to the top surface of the island 26. Then, a bonding pad provided on the top surface of the semiconductor chip 13 is connected via a fine metal wire 15 to the top surface of the lead 27. Further, the sealing resin 11 is formed so as to coat partially the island 26, the semiconductor chip 13, the fine metal wire 15 and the lead 27. In addition, a portion of the lead 27 exposed to the outside is bent downward at a right angle.

Description will be given, with reference to FIG. 9, of a process for sealing the semiconductor device 10F of the above-mentioned configuration. Here, the above-mentioned lead 27 and island 26 are supplied in the form of a lead frame 28 formed of the lead 27 and the island 26 integrally linked together in plate form. Specifically, in a unit 32 as an element unit of semiconductor device, the island 26 of a rectangular shape is disposed in the center of the unit 32, and the leads 27 extending radially outwardly are provided around the island 26. In addition, each of the leads 27 is formed of an inner lead 29 sealed with the sealing resin 11, and an outer lead 30 exposed to the outside from the sealing resin 11, and the leads 27 are linked together by a tie bar 31. Meanwhile, four corners of the island 26 are mechanically held by suspension leads extending in four directions.

A die such as is shown in FIG. 2 is used for a process for subjecting the lead frame 28 of the above-mentioned configuration to the resin sealing. Then, the semiconductor chip 13 is fixedly bonded in advance to the top surface of the island 26, and the bonding pads formed on the top surface of the semiconductor chip 13 are connected via the fine metal wires 15A and the like to the leads 27. Here, the bonding pads provided along the upper side edge, right side edge, lower side edge and left side edge, of the semiconductor chip 13 are connected respectively via the fine metal wires 15A, 15B, 15C and 15D and the like to the leads 27. The shapes, in the plan view, of the fine metal wires 15A and the like are as mentioned above.

In FIG. 9, the side edges of the cavity 17 of the molding die are shown by dash-dot lines. Further, the flow of the sealing resin is shown by thick lines. Also in this instance, the flow S of the sealing resin injected from the gate 16 is divided into the flows S1 and S2 within the cavity 17, and the flows 51 and S2 are recombined into the flow S in the vicinity of the air vent 36. Details of this are the same as those for the above-mentioned semiconductor device 10E. Then, the shapes, in the plan view, of the fine metal wires 15A and the like are the same as those in the above-mentioned semiconductor device 10E, and the fine metal wires 15A and the like are curved convexly upstream of the flow of the sealing resin 11. Specifically, as seen in the drawing, the fine metal wires 15A are curved convexly rightward, the fine metal wires 15B are curved convexly upward, the fine metal wires 15C are curved convexly rightward, and the fine metal wires 15D are curved convexly upward. This enables the prevention of the breaking of the fine metal wires 15A and the like during the resin sealing.

### Second Embodiment

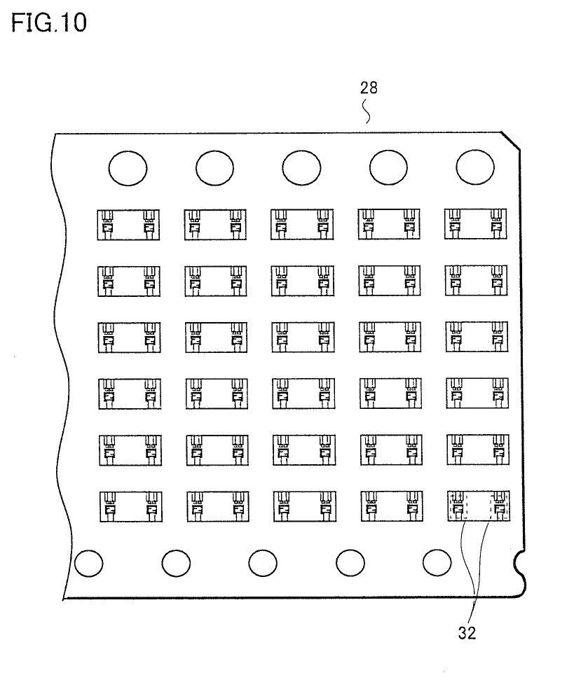

In this embodiment, description will be given, with reference to FIGS. 10 to 13, of a method of manufacturing the semiconductor devices 10A to 10F of the above-mentioned configuration. Incidentally, since the process for the resin sealing has been described in detail with reference to the first embodiment, description will be given below mainly of processes other than the resin sealing process.

First, referring to FIG. 10, the lead frame 28 is prepared in which the semiconductor chip is placed on each unit 32. Here, a pressing process or an etching process is used for preparation of the lead frame 28 provided with many units 32 of a predetermined configuration. Then, the semiconductor chip is mounted on each unit 32. Details of each unit 32 are as shown for example in FIGS. 1 and 2.

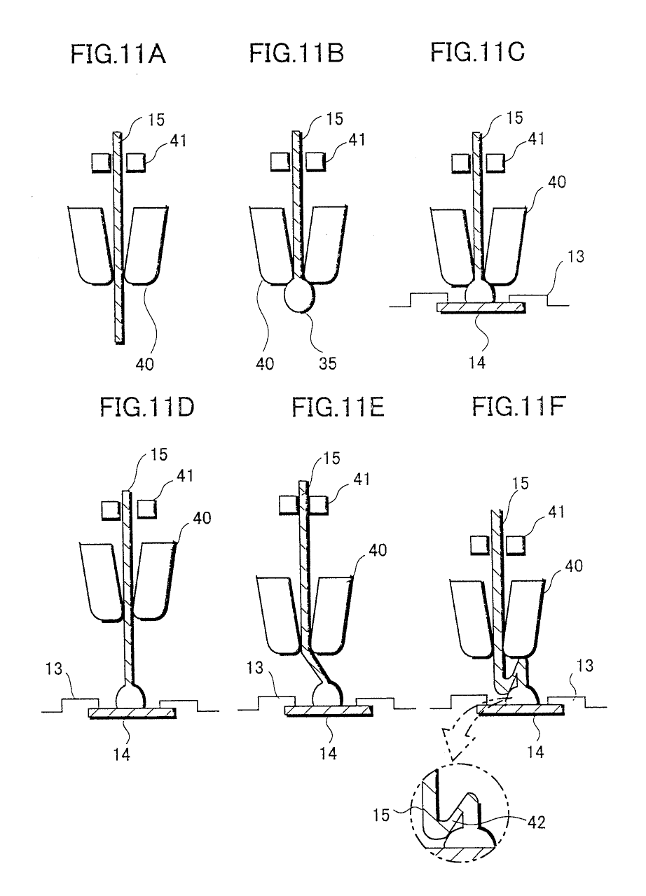

Then, referring to FIGS. 11 to 13, the fine metal wires 15 are used to provide connections between the bonding pads 14 of the semiconductor chip 13 and the top surfaces of the electrodes (or the leads). In this embodiment, the fine metal wire 15 is not in loop form but in a form such that the fine metal wire 15 is parallel to the semiconductor chip 13 and the top surface of the electrode (or the lead). This enables the lowering of the position of the topmost portion of the fine metal wire 15, and thus correspondingly reduction of the thickness of the semiconductor device manufactured.

First, as shown in FIG. 11A, a tip of the fine metal wire 15 (of 20 μm in diameter) inserted through a capillary tool 40 is melted by arc discharge or the like, thereby to form an Au ball 35 of 50 to 80 μm in diameter, utilizing surface tension, as shown in FIG. 11B.

Then, the capillary tool 40 is moved to press the Au ball 35 against the bonding pad 14, and, in this state, bonding energy (such as ultrasonic vibration, load, or heat) is applied thereby to join the fine metal wire 15 to the bonding pad 14 (See FIG. 11C).

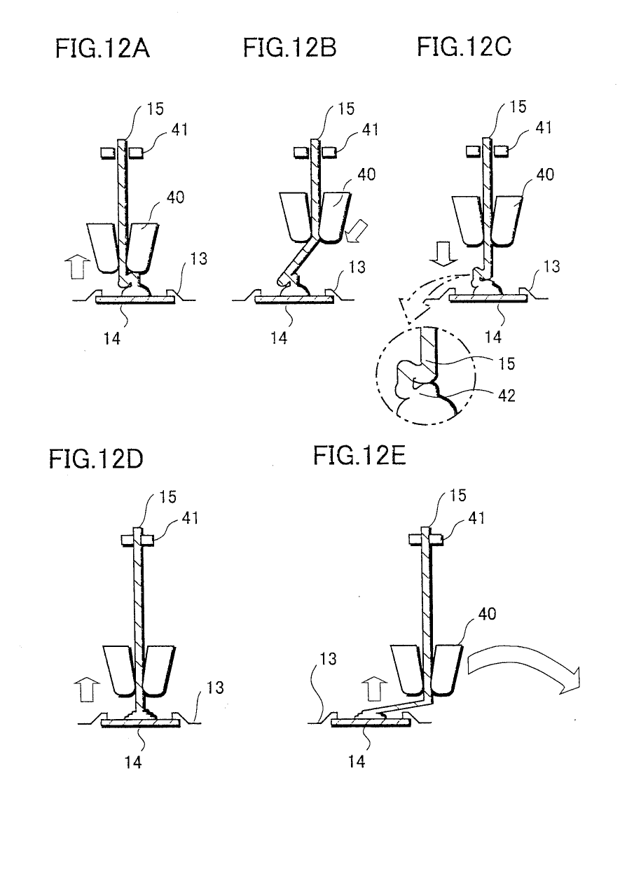

Then, the capillary tool 40 is moved upward (see FIG. 11D), and thereafter, the capillary tool 40 is moved downward in an oblique direction (i.e., at an angle of about 45° with respect to a vertical direction) so as to move away from the bonding pad 14 (see FIG. 11E), and the capillary tool 40 is pressed again against the bonding pad 14 (see FIG. 11F). Surroundings of the bonding pad 14 at this time are shown in FIG. 11F. As shown in an enlarged view of FIG. 11F, by the above-mentioned movement of the capillary tool 40, a joint portion is pressed against a head (or a lower end) of the capillary tool 40 thereby to form a thin portion 42. This creates a situation where the fine metal wire 15 is likely to break at a point of joint; however, according to the present invention, the shape, in the plan view, of the fine metal wire is in the above-mentioned curved form thereby to prevent the breaking of the fine metal wire 15 involved in the resin sealing process. Then, the capillary tool 40 is moved upward again (see FIG. 12A), and thereafter, the capillary tool 40 is moved downward in an oblique direction (i.e., at an angle of about 45° with respect to the vertical direction) opposite to the above-mentioned oblique direction shown in FIG. 11E so as to move away from the bonding pad 14 (see FIG. 12B), and the capillary tool 40 is pressed again against the bonding pad 14. Surroundings of the bonding pad 14 at this time are shown in FIG. 12C. As shown in an enlarged view of FIG. 12C, by the above-mentioned movement of the capillary tool 40, a lump of melted Au stacked in an S shape is formed on the bonding pad 14, and thereby, the fine metal wire 15 is in a state such that the fine metal wire 15 is easily pulled out horizontally (that is, the fine metal wire 15 is unlikely to be broken).

By the above-mentioned operation, the lump of melted Au is formed, but the fine metal wire 15 therearound is repeatedly plastically deformed and thus undergoes deterioration of mechanical strength. According to the present invention, the shape, in the plan view, of the fine metal wire 15 is in the curved form thereby to suppress the breaking of the fine metal wire 15 having deteriorated mechanical strength, during the resin sealing.

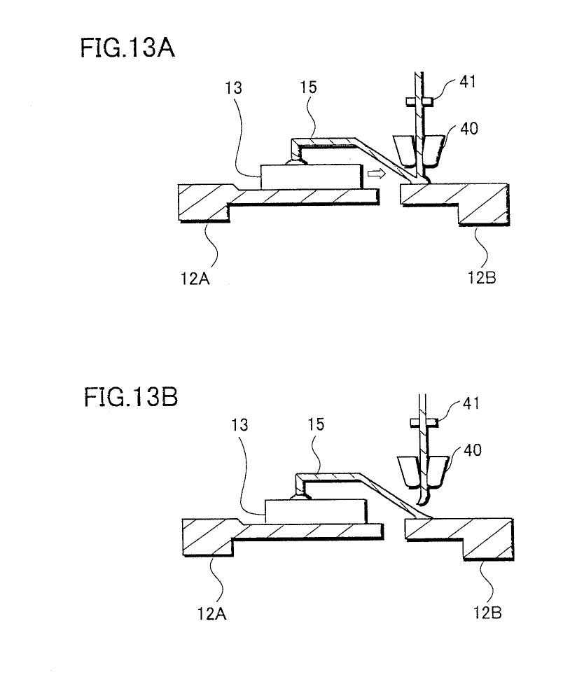

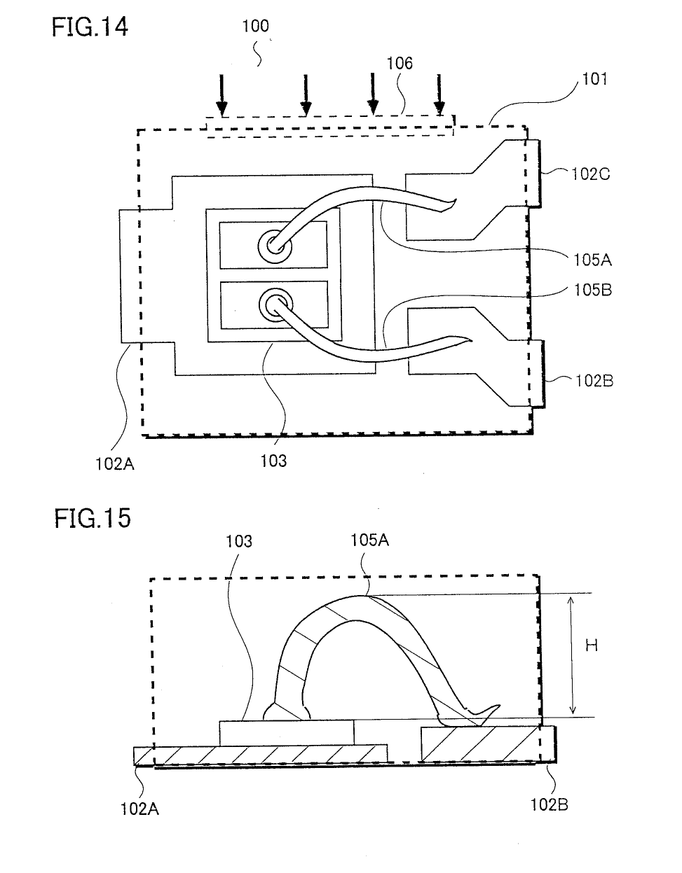

Then, the capillary tool 40 is moved slightly upward again (see FIG. 12D), and the capillary tool 40 is moved from this position in such a manner that the trajectory thereof forms a curve, thereby to pull out the fine metal wire 15 toward the electrode 12B (see FIGS. 12E and 13A). Then, the head of the capillary tool 40 is put on the top surface of the electrode 12B, the fine metal wire 15 is stitch-bonded here (see FIG. 13A), and a wire clamp 41 is closed to cut off the fine metal wire 15 (see FIG. 13B). At this time, the capillary tool 40 is moved so that the shape, in the plan view, of the fine metal wire 15 is curved convexly opposite to the direction in which the sealing resin is to be injected later.

Incidentally, the slight upward movement of a bonding wire in FIG. 12D is for the purpose of preventing the fine metal wire 15 from coming into contact with the semiconductor chip 13.

The use of the above-described method for wire bonding enables the fine metal wire 15 to be pulled out from the bonding pad 14 substantially horizontally (i.e., in a direction parallel to the top surface of the semiconductor chip), without producing high tension in the fine metal wire 15 and thus without breaking the fine metal wire 15. This makes it possible to suppress an upward rise in the fine metal wire 15, and correspondingly to suppress the thickness of a product.

In the above, the fine wire (made of gold, having a diameter of about 20 μm) can be used as the fine metal wire 15 thereby to suppress load on the electrode 12B. In addition, the use of the fine wire makes it possible to suppress strain or stress appearing on a metal surface, and thus to prevent excessive deformation in the fine metal wire 15.

The above-mentioned wire bonding process is performed for all units 32 shown in FIG. 10.

After the completion of the above-mentioned wire bonding process, the resin sealing is performed using transfer molding. Details of this process are as mentioned above with reference to FIG. 2 and others. Specifically, first, the lead frame 28 is loaded in the die of a molding device, and thereby, the units 32 provided in the lead frame 28 are individually placed in the cavities 17. Then, the sealing resin is injected from a pot provided in the molding die, into the cavities 17. Specifically, a resin lump placed in the pot is heated and becomes fluidic, is then pushed out by a plunger, is injected through a runner from the gate into the cavity, and is cooled to form a package. At this time, as mentioned above, the shape, in the plan view, of the fine metal wire is curved convexly upstream of the flow of the sealing resin being injected, and thus, the danger of the breaking of the wire or the like involved in the resin sealing is suppressed. At this time, the temperature of the die is set in the neighborhood of 180° C., for example.

After the completion of the above-mentioned process, the semiconductor device is completed through a deflashing process, a process for plating for exterior, a process for separating the units 32 from the lead frame 28, a process for screening the semiconductor devices according to electrical characteristics, a process for printing electrical characteristics, a company name, or the like on an outer surface of the sealing resin, a packing process, and so on.

The above description of the embodiments is for the purpose of facilitating the understanding of the present invention, and is not intended to limit the scope of the present invention. Of course, it is to be understood that various changes and modifications can be made without departing from the scope of the present invention, and equivalence may be included in the present invention.

For example, all fine metal wires may be curved convexly upstream of the flow of the sealing resin; alternatively, some fine metal wires may be curved concavely. If some fine metal wires are curved convexly, the fine wire having a diameter of about 20 μm may be curved convexly, and a thick wire (having a diameter of about 100 μm, for example) thicker than the fine wire may be in other forms (in a straight form or in a form curved concavely against the flow).

1. A semiconductor device comprising:
a semiconductor chip comprising a plurality of bonding pads formed thereon;
a plurality of electrodes provided near the semiconductor chip;
a plurality of fine metal wires that connect the bonding pads corresponding electrodes; and
a sealing resin that seals the semiconductor chip, the electrodes and the fine metal wires,
wherein the semiconductor device is formed by injecting the sealing resin into a cavity of a molding die from one side of the cavity, and all of the fine metal wires are curved convexly toward an inlet for the injection in plan view of the semiconductor device.

2. A semiconductor device comprising:
a semiconductor chip comprising a plurality of bonding pads formed thereon;
a plurality of electrodes provided near the semiconductor chip;
a plurality of fine metal wires that connect the bonding pads corresponding electrodes; and
a sealing resin that seals the semiconductor chip, the electrodes and the fine metal wires,
wherein all of the fine metal wires are curved in plan view of the semiconductor device, in such a manner that fixedly bonded portions located on both ends of the fine metal wires are pressurized so as to receive compressive stresses by injection pressure of the sealing resin.

3. The semiconductor device of claim 2, wherein a force of a smaller magnitude than a force applied to the fine metal wires due to the injection pressure is applied to the fixedly bonded portions.

4. A semiconductor device comprising:
a rectangular semiconductor chip;
a plurality of bonding pads disposed on the semiconductor chip and along four side edges
of the semiconductor chip;
a plurality of electrodes surrounding the semiconductor chip and provided in close proximity to the bonding pads, respectively;
a plurality of fine metal wires that connect the bonding pads and corresponding electrodes; and
a sealing resin that seals the semiconductor chip, the electrodes and the fine metal wires,
wherein the semiconductor device is formed by injecting the sealing resin along an extension line of a diagonal line of the semiconductor chip, and each of the fine metal wires is curved convexly against a flow of the sealing resin from an inlet for injection in plan view of the semiconductor device.

5. The semiconductor device of claim 4, wherein each of the fine metal wires, exclusive of fixedly bonded portions and their vicinities of the fine metal wires, extends substantially horizontally with respect to a top surface of the semiconductor chip, as viewed from a side of the semiconductor device.

6. The semiconductor device of claim 4, wherein the semiconductor chip is fixedly bonded to an island of a lead frame, and each of the electrodes is part of an inner lead of the lead frame.

7. The semiconductor device of claim 4, wherein the semiconductor chip is mounted on a substrate that comprises a printed board, a flexible sheet, an insulating substrate made of an inorganic material, or a metal substrate whose surface has been subjected to an insulation process, and each of the electrodes is provided on a top surface of the substrate.

8. The semiconductor device of claim 7, wherein the substrate includes a conductive layer having a multilayer structure.

9. The semiconductor device of claim 4, wherein each of the electrodes is sealed at top and side thereof with the sealing resin and is exposed at an underside thereof from the sealing resin.

10. A method of manufacturing a semiconductor device, comprising:
connecting a plurality of bonding pads provided on a top surface of a semiconductor chip to corresponding electrodes provided in close proximity to the semiconductor chip by corresponding fine metal wires;
loading the semiconductor chip, the fine metal wires and the electrodes in a cavity of a molding die; and
injecting a sealing resin from a gate provided in a side edge of the molding die into the cavity so as to seal the semiconductor chip, the fine metal wires and the electrodes with the sealing resin,
wherein, in plan view of the semiconductor device, all of the fine metal wires are curved convexly against a flow of the sealing resin injected from the gate.

11. The method of claim 10, wherein the fine metal wires are curved in the plan view, in such a manner that fixedly bonded portions located on both ends of the fine metal wires are pressurized by injection pressure of the sealing resin.

12. A method of manufacturing a semiconductor device, comprising:
connecting a plurality of bonding pads provided on a top surface of a semiconductor chip to corresponding electrodes provided in close proximity to the semiconductor chip by corresponding fine metal wires, the electrodes being disposed along four side edges of the semiconductor chip;
loading the semiconductor chip, the fine metal wires and the electrodes in a cavity of a molding die; and
injecting a sealing resin along an extension line of a diagonal line of the semiconductor chip into the cavity so as to seal the semiconductor chip, the fine metal wires and the electrodes with the sealing resin,
wherein, in plan view of the semiconductor device, all of the fine metal wires are curved convexly against a flow of the sealing resin from an inlet for injection.

13. A semiconductor device comprising:
a semiconductor chip comprising a plurality of bonding pads formed thereon;
a plurality of electrodes provided near the semiconductor chip;
a plurality of fine metal wires that connect the bonding pads and corresponding electrodes; and
a sealing resin that seals the semiconductor chip, the electrodes and the fine metal wires,
wherein in plan view of the semiconductor device all of the fine metal wires are curved toward the same side of the semiconductor device.

14. A semiconductor device comprising:
a semiconductor chip comprising a plurality of bonding pads formed thereon along a first side of the semiconductor chip;
a plurality of electrodes provided outside the semiconductor chip and along the first side of the semiconductor chip;
a plurality of fine metal wires that connect the bonding pads and corresponding electrodes; and
a sealing resin that seals the semiconductor chip, the electrodes and the fine metal wires,
wherein in plan view of the semiconductor device all of the fine metal wires are curved toward a second side of the semiconductor chip.

15. The semiconductor device of claim 14, further comprising a plurality of additional bonding pads formed on the semiconductor chip along the second side of the semiconductor chip, a plurality of additional electrodes provided outside the semiconductor chip and along the second side of the semiconductor chip, and a plurality of additional fine metal wires that connect the additional bonding pads and corresponding additional electrodes, wherein the sealing resin seals the additional electrodes and the additional fine metal wires, and in the plan view of the semiconductor device all of the additional fine metal wires are curved toward the first side of the semiconductor chip.
